(19) United States
(12) Patent Application Publication
(10) Pub. No.: US 2023/0352387 A1
(43) Pub. Date: Nov. 2, 2023

(54) Built-In Serial Via Chain for Integrity Monitoring of Laminate Substrate

(71) Applicant: Texas Instruments Incorporated, Dallas, TX (US)

(72) Inventors: Li Jiang, Allen, TX (US); Yiqi Tang, Allen, TX (US); Usman Mahmood Chaudhry, McKinney, TX (US); Thiha Shwe, Wylie, TX (US)

(21) Appl. No.: 17/733,414

(22) Filed: Apr. 29, 2022

(51) Int. Cl. H01L 23/498; H01L 23/00; H01L 21/66

(52) U.S. Cl. CPC H01L 23/49827; H01L 23/49816; H01L 24/17; H01L 22/34; H01L 2224/1413; H01L 2224/1403

(57) ABSTRACT

An example semiconductor package comprises an integrated circuit die having a first surface with a first array of electrode pads. A laminate substrate has an upper surface with a second array of electrode pads. The electrode pads of the first array are connected to corresponding electrode pads of the second array using a solder bump. The laminate substrate has a lower surface with a third array of electrode pads. The electrodes of the third array are coupled to corresponding electrodes of the second array by a laminate wiring structure within the laminate substrate. A first electrode on the lower surface is coupled to a second electrode on the lower surface by a chain of vias through the laminate substrate. The chain of vias is not connected to the integrated circuit die.

### BACKGROUND

Flip chip technology allows a semiconductor die or integrated circuit (IC) chip to be electrically connected to a package substrate, such as a chip carrier or laminate substrate. The package substrate may then be mounted on a printed circuit board (PCB). Flip chip microelectronic assembly involves direct electrical connection of face-down or “flipped” IC chips onto the package substrate using conductive bumps on IC chip bond pads. Flip chip ball grid array (BGA) packages provide design flexibility to incorporate higher signal density and overall IC functionality into a small footprint.

Flip chip BGA packages can be mounted using standard printed circuit board assembly techniques. The package substrate typically includes internal wiring comprising microvias that interconnect across substrate layers for signal routing between the IC chip and the PCB or a host circuit. Microvia cracking can be caused by mechanical stresses caused, for example, by temperature excursions from reflow of soldered connections and/or by thermal fluctuations during assembly of components. Cracking or other compromise of the microvias can lead to loss of signal integrity and reduced device performance.

### SUMMARY

An example semiconductor package comprises an integrated circuit (IC) die having a first surface with a first array of electrode pads. A laminate substrate has an upper surface with a second array of electrode pads. The electrode pads of the first array are connected to corresponding electrode pads of the second array using a solder bump. The laminate substrate has a lower surface with a third array of electrode pads. The electrodes of the third array are coupled to corresponding electrodes of the second array by a laminate wiring structure within the laminate substrate. A first electrode on the lower surface is coupled to a second electrode on the lower surface by a chain of vias through the laminate substrate. The chain of vias is not connected to the IC die.

The chain of vias includes core vias in a laminate core layer and microvias in one or more dielectric layers. The one or more dielectric layers comprise dielectric layers both above and below the laminate core layer. A top solder resist layer is placed above a top dielectric layer and a bottom solder resist layer is placed below a bottom dielectric layer.

The chain of vias may include examples having microvias in a plurality of coreless dielectric layers.

The semiconductor package may have a majority of microvias in a via chain arranged in a stacked format, in an offset format, or in both groups of stacked microvias and groups of offset microvias.

The number of microvias in the via chain may be selected to create a target resistance value across the chain of vias. The chain of vias and the laminate wiring structure are constructed by a same process to create the laminate substrate.

An example method for testing substrate integrity comprises providing a semiconductor package including an integrated circuit (IC) die coupled to a laminate substrate. The laminate substrate has a surface with a plurality of contacts. A first contact on the surface is coupled to a second contact on the surface by a chain of vias through the laminate substrate. The method further includes connecting voltage probes to the first contact and the second contact and connecting current probes to the first contact and the second contact. The method then determines a resistance value across the chain of vias based upon voltage and current measurements generated using the voltage and current probes and evaluates whether the resistance value indicates cracking in the chain of vias. Cracking in the chain of vias is indicated when the resistance value exceeds a target value by a threshold amount.

### BRIEF DESCRIPTION OF THE DRAWINGS

Having thus described the invention in general terms, reference will now be made to the accompanying drawings, wherein:

FIG. 1 is a cross section view of an example Flip Chip Ball Grid Array (FCBGA) package adapted to incorporate the via chain design disclosed herein.

FIG. 2 is a cross section view of a laminate substrate with an embedded via chain illustrating a stacked-via configuration.

FIG. 3 is a cross section view of a laminate substrate with an embedded via chain illustrating an offset-via configuration.

FIG. 4 is a cross section view of coreless structure with an embedded via chain.

FIGS. 5A-C illustrates a method for estimating resistance in a structure having two stacked microvias.

FIG. 6 illustrates a semiconductor package having a laminate substrate with an embedded via chain that is adapted to support testing of the device.

FIG. 7 is a graph illustrating the likelihood that cracked microvias are present in a laminate substrate in view of measured resistance for an example via chain design.

FIG. 8 illustrates an example microvia configuration adapted for creating a long via chain.

FIG. 9 illustrates an example microvia configuration having a hybrid combination of stacked and offset microvias.

FIG. 10 illustrates a loop-back microvia configuration between a single pair of solder balls.

FIG. 11 illustrates a loop-back microvia configuration with additional solder balls.

### DETAILED DESCRIPTION

The present disclosure is described with reference to the attached figures. The figures are not drawn to scale, and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

Corresponding numerals and symbols in the different figures generally refer to corresponding parts, unless otherwise indicated. The figures are not necessarily drawn to scale. In the drawings, like reference numerals refer to like elements throughout, and the various features are not necessarily drawn to scale. In the following discussion and in the claims, the terms “including,” “includes,” “having,” “has,” “with,” or variants thereof are intended to be inclusive in a manner similar to the term “comprising,” and thus should be interpreted to mean “including, but not limited to . . . ” Also, the terms “coupled,” “couple,” and/or or “couples” is/are intended to include indirect or direct electrical or mechanical connection or combinations thereof. For example, if a first device couples to or is electrically coupled with a second device that connection may be through a direct electrical connection, or through an indirect electrical connection via one or more intervening devices and/or connections. Terms such as “top,” “bottom,” “front,” “back,” “over,” “above,” “under,” “below,” and such, may be used in this disclosure. These terms should not be construed as limiting the position or orientation of a structure or element but should be used to provide spatial relationship between structures or elements.

The term “semiconductor device” is used herein. A semiconductor device can be a discrete semiconductor device such as a bipolar transistor, a few discrete devices such as a pair of power FET switches fabricated together on a single semiconductor die, or a semiconductor die can be an integrated circuit with multiple semiconductor devices such as the multiple capacitors in an A/D converter. The semiconductor device can include passive devices such as resistors, inductors, filters, sensors, or active devices such as transistors. The semiconductor device can be an integrated circuit with hundreds or thousands of transistors coupled to form a functional circuit, for example a microprocessor or memory device. The semiconductor device may also be referred to herein as a “semiconductor die” or an integrated circuit (IC) die.

The term “semiconductor package” is used herein. An integrated circuit package has at least one semiconductor device electrically coupled to terminals and has a package body that protects and covers the semiconductor device. In some arrangements, multiple semiconductor devices can be packaged together. For example, a power field effect transistor (FET) semiconductor device and a second semiconductor device (such as a gate driver die, or a controller die) can be packaged together to from a single packaged electronic device. Additional components such as passives can be included in the packaged electronic device. The semiconductor device is mounted with a package substrate that provides conductive leads. A portion of the conductive leads form the terminals for the packaged device. In wire bonded integrated circuit packages, bond wires couple conductive leads of a package substrate to bond pads on the semiconductor device. The integrated circuit package can have a package body formed by a thermoset epoxy resin mold compound in a molding process, or by the use of epoxy, plastics, or resins that are liquid at room temperature and are subsequently cured. The package body may provide a hermetic package for the packaged device. The package body may be formed in a mold using an encapsulation process, however, a portion of the leads of the package substrate are not covered during encapsulation, these exposed lead portions form the terminals for the integrated circuit package. The integrated circuit package may also be referred to as a “integrated circuit package.”

A package substrate is a substrate arranged to receive a semiconductor die and to support the semiconductor die in a completed semiconductor device package. Package substrates useful with the arrangements include conductive lead frames, which can be formed from copper, aluminum, stainless steel, steel, and alloys such as Alloy 42 and copper alloys. The lead frames can include a die pad with a die side surface for mounting a semiconductor die, and conductive leads arranged near and spaced from the die pad for coupling to bond pads on the semiconductor die using wire bonds, ribbon bonds, or other conductors. In example arrangements, a heat slug is attached to the package substrate, and the heat slug has a die mounting area for mounting semiconductor devices. The lead frames can be provided in strips or arrays. The conductive lead frames can be provided as a panel with strips or arrays of unit device portions in rows and columns. Semiconductor devices can be placed on respective unit device portions within the strips or arrays. A semiconductor device can be placed on a die mount area for each packaged semiconductor device. Die attach or die adhesive can be used to mount the semiconductor devices. In wire bonded packages, bond wires can couple bond pads on the semiconductor devices to the leads of the lead frames. The lead frames may have plated portions in areas designated for wire bonding, for example silver, nickel, gold, or palladium plating can be used. After the bond wires are in place, a portion of the package substrate, the semiconductor device, and at least a portion of the die pad can be covered with a protective material such as a mold compound. More than one semiconductor device can be mounted to a package substrate for each unit.

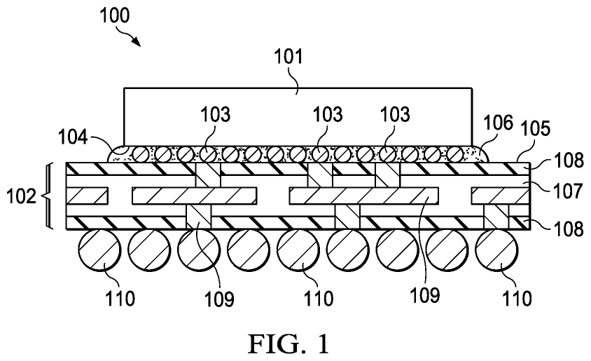

FIG. 1 is a cross section view of an example Flip Chip Ball Grid Array (FCBGA) package 100. An integrated circuit (IC) die 101 is mounted on a laminate substrate 102 using a plurality of conductive bumps 103. IC die 101 has a number of bond pads on surface 104. Conductive bumps 103 are placed directly on the bond pads during wafer processing. The bumped IC die 101 is then flipped and placed so that surface 104 faces down. The bumps 103 then contact landing pads on the top surface 105 of laminate substrate 102. The bumps 103 are reflowed to bond IC die 101 and substrate 102 together. An underfill 106 is deposited in between IC die 101 and substrate 102. In some examples a lid (not shown) may be placed over package 100 to cover IC die 101 and surface 105 on substrate 102. In other examples, instead of bonding an IC die 101 to the substrate 102, other components such as passive filters, sensors, detector arrays, and micro-electromechanical systems (MEMS) devices may be used in flip chip form.

The laminate substrate 102 may be, for example, a multi-layered component having a glass/resin, organic, or ceramic core 107. Ajinomoto build-up film (ABF) or similar films are used to build up dielectric layers 108 above and below the core material 107. The dielectric layers 108 include embedded copper layers These copper layers are responsible for distributing signals and power across the package 100. Multiple metallic vias 109 through core 107 and dielectric layers 108 electrically couple the external landing pads on the top surface 105 to solder balls 110. Solder balls 110 may be made from various conductive materials. Solder balls 110 may be further attached to a printed circuit board (PCB) (not shown) to enable electrical connections between IC die 101 and various external components.

The integrity of substrate vias 109 is an important consideration for laminate BGA packages. This can be especially important for applications that have safety concerns, such vehicle-installed devices where the industry requires zero defects (0 DPPM). In existing devices, substrate via cracks are extremely difficult to detect during semiconductor device-level qualification and product screening. As a result, defects are often not found until the devices are at the end customer and the final product is found to fail testing. Identifying the root causes for via cracks is challenging due to the extremely high cost for failure analysis and the long cycle times for final product completion. In many cases, the real root causes cannot be identified. Applying conservative via design rules might be used to reduce via integrity risks; however, such solutions result in increasing substrate and package sizes, which reduces competitiveness in the device market. In many cases, it is difficult to fully validate whether a low-DPPM via-crack problem is caused by a substrate manufacturing issue or a design issue.

Failures are often the result of cracking due to stress on the device. Vias are only a small percentage of the cracked area due to package-level stresses. A typical substrate netlist may consist of a single via or a limited number of vias in the loop. The resistance change resulting from a few damaged vias is too small to be detected by typical electrical testing, such as a two-wire resistance measurement. Even under four-wire Kelvin sensing measurements, the early stages of via cracking are hard to detect. Via cracks are usually related to substrate manufacturing issues, which is an extremely complicated process. Each step requires control on several different process factors, such as bath cleanliness, temperature, pH, etc. When a via crack is detected at the end customer, the substrate has moved far beyond the manufacturing phase and has been assembled into a package, mounted onto a module, and integrated into a system board. This often involves a supply chain of five or more companies. Typically, a via crack is detected more than 18 months after the substrate was manufactured by the original vendor. When the via crack is on a device requiring a low DPPM, it may be difficult to determine the root cause within the substrate manufacturing process. Additionally, failure analysis on via cracks is commonly performed using advanced electron microscopy techniques, such as using expensive Scanning Electron Microscopy (SEM) or Transmission Electron Microscopy (TEM) technologies.

There is no existing method to predict or screen for via-cracked devices at the unit level. Instead, existing solutions use a via chain coupon at the edge or margin of a substrate panel or strip, which may comprise hundreds of individual units. Accordingly, current testing is performed only at the panel or strip level. Such testing does not analyze the final product structure and, therefore, cannot verify unit-level via 1cracking.

In an example laminate substrate, a built-in via chain is included at the unit level for via integrity monitoring. Accordingly, each of the units on a substrate panel or strip may include an individual via chain for testing. The unit-level via chain is manufactured using exactly the same process as the entire substrate, including the operating portion of each unit. The unit-level via chain includes a large number of stacked vias or staggered vias arranged in series. By including a large number of vias, the total resistance across the via chain increases when the cracks occur at multiple vias. This allows via cracks to be detectable at the unit level. Such via chains can be designed to reside in the build-up layers above and/or below the laminate substrate core. Depending on the number of available BGA solder balls, each test via-chain netlist can be design for either two-wire or four-wire testing configurations. Additionally, the test via chain provides a build-in monitoring cell that can used to check the integrity of substrate vias at different phases of the product lifecycle, such as at substrate, device, module, and system manufacturing and assembly stages. This will help to achieve a zero DPPM target, which no existing solution can provide at the unit level.

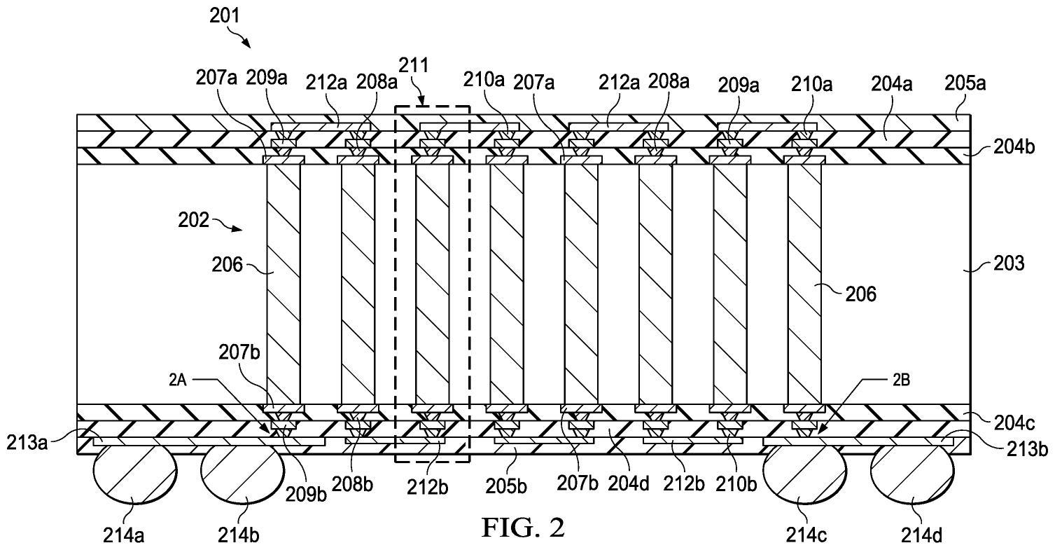

FIG. 2 is a cross section view of a laminate substrate 201 with an embedded via chain 202 illustrating a stacked-via configuration. Laminate substrate 201 comprises a core layer 203, build-up insulating layers 204a-d, and solder resist layers 205a,b. Core layer 203 may comprise a glass/resin material in one example, such as a woven glass cloth impregnated with a thermosetting resin, epoxy resin, bismaleimide triazine resin, or the like. Build-up layers 204a-d may comprise thin dielectric films in one example. The dielectric layers may be added as build-up films, such as layers of Ajinomoto Build-up Film (ABF), that are applied on the top and bottom surfaces of core layer 203. Solder resist layers 205a,b are applied on the upper and lower surface of the outer build-up layers 204a and 204d, respectively. Solder resist layers 205a,b may be a thin layer of polymer applied for protection against oxidation and to prevent solder bridges from forming between closely spaced contacts that are formed on the surface of laminate substrate 201.

Via chain 202 includes a plurality of core vias 206 formed through core layer 203. Core vias 206 comprise a conductive material, such as copper, embedded in holes that penetrate from a top surface to a bottom surface of core layer 203. Conductive plating 207a,b is formed on the top and bottom of each core via 206 within build-up layers 204b,c. Microvias 208a,b are then formed in build-up layers 204b,c. Microvias 208a,b may be formed by laser drilling holes in build-up layers 204b,c and then filling the holes with conductive material, such as copper. Conductive plating 209a,b is formed on the top and bottom of each microvia 208a,b within build-up layers 204a,d. Additional microvias 210a,b are then formed in build-up layers 204a,d. Microvias 210a,b are aligned vertically with microvias 208a,b and may be formed in a similar manner as microvias 208a,b. This vertical alignment of microvias 208a,b and 210a,b is referred to herein as a stacked configuration.

A conductive path is formed through each stacked series of elements 211, which includes microvia 210a, conductive plating 209a, microvia 208a, core via 206, microvia 208b, conductive plating 209b, and microvia 210b. Adjacent ones of these elements 211 are linked together by conductive plating 212a,b formed on the top or bottom surface of build-up layers 204a,d, respectively. By alternating the elements 211 linked by conductive plating 212a and 212b, a relatively long chain 202 of microvias 208, 210 and core vias 206 is formed from an endpoint 2A to an endpoint 2B. Conductive pads 213a,b, such as electrodes or land pads, are formed on the bottom surface of build-up layer 204d. Each conductive pad 213a,b is electrically connected to a microvia 210b in buildup layer 204d at an endpoint 2A or 2B of via chain 202. Solder balls 214a,b are electrically connected to conductive pad 213a, and solder balls 214c,d are electrically connected to conductive pad 213b. Solder resist layers 205a,b are formed on top or bottom of conducive plating 212a,b and exposed portions of conductive pads 213a,b. Although two solder balls 214 are shown as attached to each conductive pad 213, in other examples a single solder ball may be connected to each conductive pad 213a,b.

As discussed in more detail hereinbelow, test equipment may be coupled to solder balls 214a-d to measure a resistance value across via chain 202. The measured resistance value may be compared to an expected or target resistance value. Differences between the measured and target values may be used to determine whether cracking is present in laminate substrate 201.

While eight core vias 206 are shown in FIG. 2, in other examples more or fewer core vias may be included in the via chain. Additionally, while two microvias 208, 210 are shown as stacked at each end of core vias 206, in other examples any number of additional dielectric layers with corresponding numbers of microvias may be built-up above and below core layer 203. While the number of microvias above and below each core via 206 in the illustrated example are equal, (i.e., two microvias above and below each core via), in other examples one side of each core via may have more microvias than the other side. Moreover, each stacked element 211 may have varying numbers of microvias above and below the core via 206.

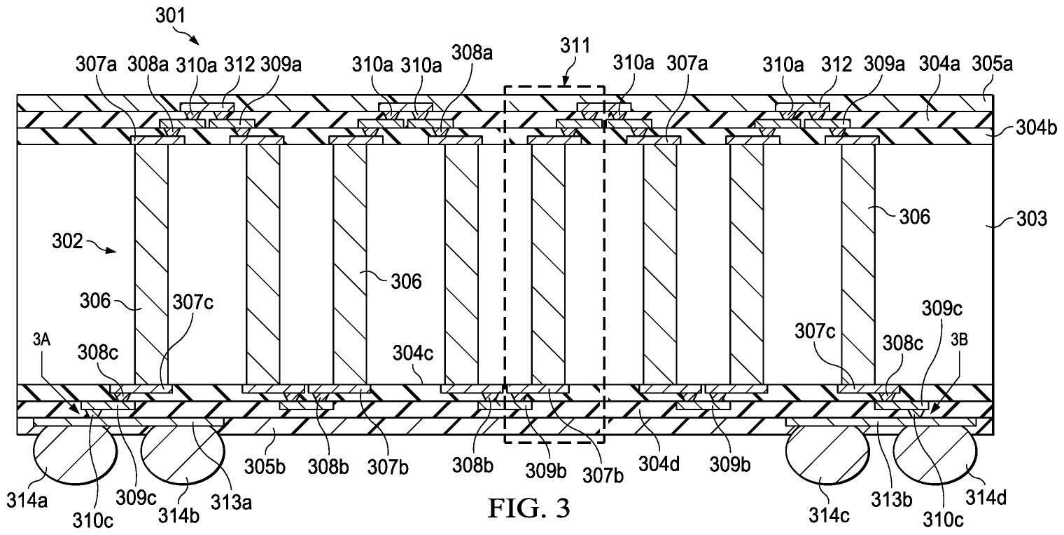

FIG. 3 is a cross section view of a laminate substrate 301 with an embedded via chain 302 illustrating an offset-via configuration. Laminate substrate 301 comprises a core layer 303, build-up insulating layers 304a-d, and solder resist layers 305a,b. Core layer 303 may comprise a glass/resin material in one example, such as a woven glass cloth impregnated with a thermosetting resin, epoxy resin, bismaleimide triazine resin, or the like. Build-up layers 304a-d may comprise thin dielectric films in one example. The dielectric layers may be added as a build-up film, such as ABF, that is applied on each side of core layer 303. Solder resist layers 305a,b are applied on the upper and lower surface build-up layers 304a and 304d, respectively.

Via chain 302 includes a plurality of core vias 306 formed in core layer 303. Core vias 306 comprise a conductive material, such as copper, embedded in holes that penetrate from a top surface to a bottom surface of core layer 303. Conductive plating 307a,b is formed on the top and bottom of each core via 306 within build-up layers 304b,c. Microvias 308a,b are then formed in build-up layers 304b,c adjacent to conductive plating 307a,b. Microvias 308a,b are offset laterally from core vias 306. Microvias 308a,b are electrically connected to core vias 306 by a respective conductive plate 307a,b. Additional conductive plating 309a,b is formed on the top and bottom of each microvia 308a,b within build-up layers 304a,d. In bottom build-up layer 304d, the conductive plates 309b overlap adjacent microvias 308b thereby creating an electrical connection between pairs of microvias 308b.

Microvias 310a are formed in top build-up layer 304a. Microvias 310a are formed above and adjacent to conductive plates 309a but offset from microvias 308a. A conductive path is formed across each offset series of elements 311, which includes microvia 310a, conductive plating 309a, microvia 308a, core via 306, conductive plating 307b, and microvia 308b. Adjacent ones of these elements 311 are linked together on the bottom side by conductive plating 309a,b formed in build-up layer 304d. On the top side of each offset series of elements 311, adjacent microvias 310a are electrically coupled together by conductive plating 312.

Additional microvias 308c are formed in bottom build-up layer 304c near the outermost core vias 306. Microvias 308c are electrically connected to the outermost core vias 306 by a respective conductive plate 307c. Microvias 310c are formed in build-up layer 304d. Microvias 310c are offset from microvias 308c in build-up layer 304c but are electrically coupled to microvias 308c by conductive plating 309c.

By alternating the elements 311 linked by conductive plating 312 on top and conductive plating 309b on the bottom, a relatively long chain 302 of microvias 308, 310 and core vias 306 is formed from an endpoint 3A to an endpoint 3B. Conductive pads 313a,b, such as electrodes or land pads, are formed on the bottom surface of build-up layer 304d. Each conductive pad 313a,b is electrically connected to a microvia 310c in buildup layer 304d at an endpoint 3A and 3B of via chain 302. Solder balls 314a,b are electrically connected to conductive pad 313a, and solder balls 314c,d are electrically connected to conductive pad 313b. Solder resist layers 305a,b are formed on top or bottom of conducive plating 312 and exposed portions of conductive pads 313a,b.

As discussed in more detail hereinbelow, test equipment may be coupled to solder balls 314a-d to measure a resistance value across via chain 302. The measured resistance value may be compared to an expected or target resistance value. Differences between the measured and target values may be used to determine whether cracking is present in laminate substrate 301.

While eight core vias 306 are shown in FIG. 3, in other examples more or fewer core vias may be included in the via chain. In other examples any number of additional dielectric layers with corresponding microvias may be built-up above and below core layer 303. In other examples, each element 311 may have any number of microvias above and below the core via 306. In further examples, a single solder ball may be connected to each conductive pad 313a,b.

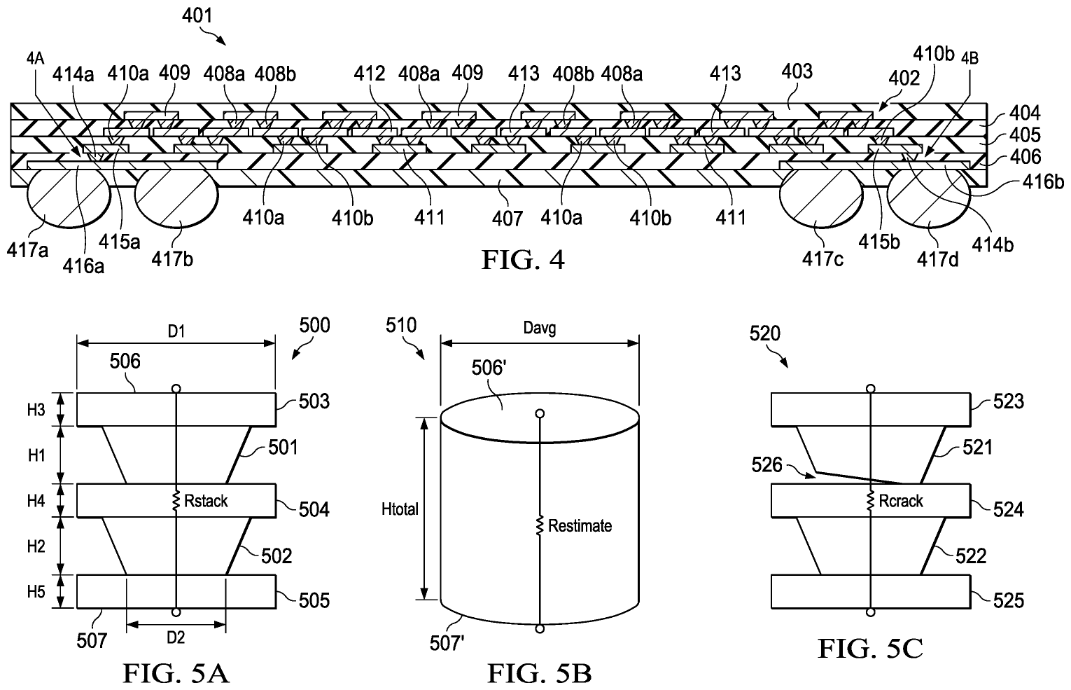

FIG. 4 is a cross section view of coreless structure 401, such as an Embedded Trace Substrate (ETS), with an embedded via chain 402. In one example, structure 401 is a circuit board with a circuit pattern formed within insulating layers. Coreless structure 401 includes a plurality of dielectric layers 403-406 and a solder resist layer 407. Coreless structure 401 may be used for packaged IC structures that require a small form factor and thin profile, such as for mobile applications. In one example, an IC die may be attached to contacts (not shown) on top dielectric layer 403.

Dielectric layers 403-406 may comprise thin films, such as ABF. Pairs of microvias 408a,b are formed in dielectric layer 404. These microvia pairs 408a,b are electrically coupled by a conductive plate 409 formed on layer 404 or in a dielectric layer 403. Additional pairs of microvias 410a,b are formed in dielectric layer 405 and are electrically coupled by a conductive plate 411. Adjacent ones of microvias 408b and 410a are electrically coupled by conductive plating 412. As illustrated in via chain 402, the microvias 408b and 410a are offset from each other laterally. In other examples, microvias 408b and 410a may be formed in a stacked configuration. In further examples, some adjacent microvias 408b and 410a may be stacked while other microvias 408b and 410a are offset.

Adjacent ones of microvias 410b and 408a are electrically coupled by conductive plating 413. As illustrated in via chain 402, the microvias 410b and 408a are offset from each other laterally. In other examples, microvias 410b and 408a may be formed in a stacked configuration or in a mixed stacked and offset configuration.

As shown in the illustration, a left-most microvia 410a is formed in dielectric layer 406. Microvia 414a is laterally offset from the left-most microvia 410a but electrically coupled to that microvia 410a by conductive plating 415a. Similarly, a right-most microvia 410b is formed in dielectric layer 406. Microvia 414b is laterally offset from the right-most microvia 410b but electrically coupled by conductive plating 415a to that microvia 410b.

Via chain 402 includes microvias 408, 410, and 414, which are electrically linked using conductive plates 409, 411, 412, 413, and 415, to create a chain of elements from an endpoint 4A to an endpoint 4B. Conductive pads 416a,b, such as electrodes or land pads, are formed on the bottom surface of build-up layer 406. Each conductive pad 416a,b is electrically connected to a microvia 414a,b in buildup layer 406 at an endpoint 4A and 4B of via chain 402. Solder balls 417a,b are electrically connected to conductive pad 416a, and solder balls 417c,d are electrically connected to conductive pad 416b. Solder resist layer 407 is formed on the bottom of dielectric layer 406 and exposed portions of conductive pads 416a,b. In some examples layer 403 may be a solder resist material or a solder resist layer (not shown) may be formed on top of layer 403.

As discussed in more detail hereinbelow, test equipment may be coupled to solder balls 416a-d to measure a resistance value across via chain 402. The measured resistance value may be compared to an expected or target resistance value. Differences between the measured and target values may be used to determine whether cracking is present in laminate substrate 401.

While only two layers of offset microvias 408, 410 are shown in FIG. 4, in other examples additional dielectric layers may be included in structure 401 with additional microvias included in the via chain. In further examples, a single solder ball 417a,c may be connected to each conductive pad 416a,b.

FIG. 5A illustrates a structure 500 having two stacked microvias 501 and 502. Microvias 501, 502 are coupled to conductive plating layers 503-505. In one example, microvias 501, 502 are formed in a dielectric layer of a laminate substrate or a coreless substrate. Microvias 501, 502 and conductive plates 503-505 are conductive routing features that are created using copper, aluminum, or other conductive material. Features of microvias 501, 502 and conductive plates 503-505 can be used to estimate a resistance Rstack across structure 500 from a top surface 506 to a bottom surface 507.

Microvias 501, 502 have heights of H1 and H2, respectively. Conductive plates 503-505 have heights of H3-H5, respectively. The diameter of structure 500 varies due to the combination of microvias 501, 502 and conductive plates 503-505. The widest diameter along the conductive path from surface 506 to surface 507 is the width D1 of the conductive plates 503-505. The narrowest diameter along that path is the width D2 at the base of the microvias 501, 502.

FIG. 5B illustrates a model microvia stack 510 representing the stacked microvia structure 500 shown in FIG. 5A. The diameter Davg and height Htotal used for the model microvia stack 510 correspond to the features of microvia structure 500. Using model 510 a microvia resistance value Restimate can be calculated. The value of Restimate approximates the resistance Rstack across microvia stack 500.

Diameter Davg is an average diameter and, in one example, represents an average of the widest (D1) and narrowest (D2) diameters of microvia structure 500. Height Htotal represents the total height of microvia structure 500 or, in one example, the sum of values H1 to H5. An estimated resistance value Restimate can be calculated using the diameter Davg and height Htotal of the model microvia stack 510. Resistance in a conductor can be calculated using the equation: R=ρ(L/A), where ρ is the resistivity of the conductor material, L is the length of the conductor, and A is the area of the conductor. Assuming that microvia 500 is a copper conductor, the value of ρ is 1.7×10⁻⁸ Ω-m for copper. The length L is Htotal. The area A can be calculated using πr², where r is Davg/2. Accordingly, the value of Restimate is calculated from these values using the resistance equation.

In one example, Restimate is 0.91 mΩ, which represents the resistance Rstack for microvia structure 500 when there are no cracks or defects in structure 500. This resistance value is very small and is difficult to measure since it may be close to a measurement noise floor. Additionally, this small value is subject to measurement tolerances such as contact resistance. Larger resistance values would be more useful in testing and for evaluating laminate substrates for cracking. A number of microvia structures can be connected together to form a via chain, such as via chains 202, 302, and 402 shown in FIGS. 2, 3, and 4. The more microvias included in the chain, the higher the resistance value will be across the entire via chain. In one example, a series of forty microvia structures 500 may be changed together to create a via chain having an expected resistance of approximately 40 mΩ across the entire chain, i.e., where Restimate of individual elements is 0.91 mΩ.

FIG. 5C illustrates a structure 520 having two stacked microvias 521 and 522 coupled to conductive plating layers 523-525. Microvia structure 520 may be embedded within a laminate substrate. A crack 526 has developed between microvia 521 and conducive plate 524. Crack 526 may have developed during manufacturing of the laminate substrate as the result of thermal stress and may vary in degree from 1% to 99% of the interface between microvia 521 and conducive plate 524. The presence and degree of crack 526 could be detected using SEM or TEM inspection, which is impractical and prohibitively expensive. Accordingly, other methods for detecting crack 526 are needed. Crack 526 causes an increase in the resistance Rcrack across structure 520. Even if structures 510 and 520 have the same parameters and created from the same materials, the value of Rcrack will be greater than the value of Rstack. This increase in resistance can be used to identify the likelihood that cracks 526 or other defects are present in a microvia structure, such as a via chain.

The illustrated example of calculating an estimate via chain resistance in FIGS. 5A-C is highly simplified. In other examples, the via chain may include core vias, offset vias, and varying lengths of conductive plating between vias. The estimated resistance across a via chain having any configuration of vias may be calculated for other example via chains.

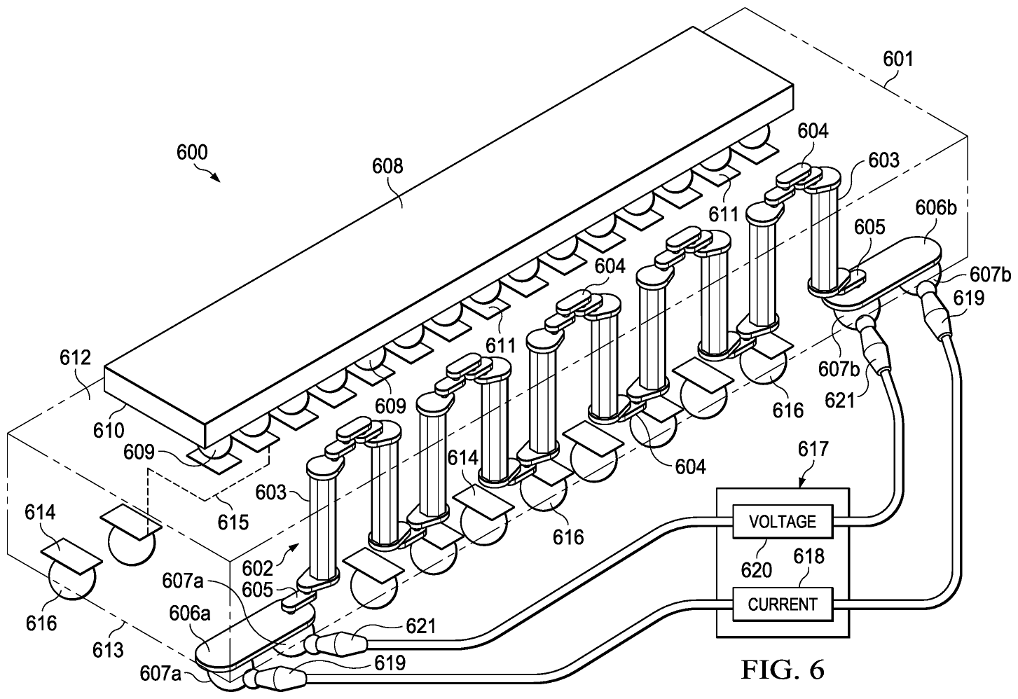

FIG. 6 illustrates a semiconductor package 600 having a laminate substrate 601 with an embedded via chain 602. For simplification of the illustration, the core and build-up layers of laminate substrate are not shown. Via chain 602 includes a plurality of core vias 603 that are interlinked with a plurality of offset microvias 604. Via chain 602 is electrically coupled via microvias 605 to electrodes 606a,b on the bottom surface of laminate substrate 601. Solder balls 607a,b are electrically coupled to electrodes 606a and 606b, respectively. Via chain 602 creates an electrical path between solder balls 607a and solders balls 607b across laminate substrate and through multiple layers of build-up and core materials.

In one example, an IC die 608 is mounted on laminate substrate 601 using a plurality of solder bumps 609. An array of electrode pads (not shown) are formed on surface 610 of IC die 608. Another array of electrode pads 611 are formed on the upper surface 612 of laminate substrate 601. The electrode pads on surface 610 are connected to corresponding electrode pads 611 on surface 612 using solder bumps 609. Laminate substrate 601 has a lower surface 613 with another array of electrode pads 614. The electrode pads 614 on surface 613 are coupled to corresponding electrode pads 611 on surface 612 by a laminate wiring structure 615 within the laminate substrate 601. Laminate wiring structure 615 is formed using core vias, microvias, and conductive plating in the same manner as via chain 602. Solder balls 616 are electrically coupled to electrode pads 614. Electrical signal paths are created from individual ones of solder balls 616 to IC die 608 across electrode pad 614, wiring structure 615, electrode pads 611, solder bumps 609, and electrode pads on surface 610. These electrical signal paths allow IC die 608 to communicate with external devices, such as a PCB (not shown), through solder balls 616.

In one example, solder balls 607a and 607b may be considered dummy balls that do not provide a signal path to IC die 608. Likewise, via chain does not provide a connection to IC die 608, electrode pads 611, electrode pads 614, internal wiring 615, or solder balls 616. Via chain 602 is manufactured using exactly the same process as the other components of laminate substrate 601 and, therefore, is subject to the same stresses as internal wiring structure 615, for example. Consequently, if microvias in internal wiring 615 are cracked or damaged, then corresponding microvias in via chain 602 are likely to also be cracked or damaged. The corresponding microvias may be, for example, microvias in the same build-up layer.

The integrity of the core vias and microvias in via chain 602 may be tested using four-wire, Kelvin sensing measurement equipment 617. A current measurement circuit 618 is coupled to probes 619, which may be attached to solder balls 607a and 607b to measure a current through via chain 602. A voltage measurement circuit 620 is coupled to probes 621, which may be attached to solder balls 607a and 607b to measure a voltage across via chain 602. Using the equation R=V/I and the measured current and voltage, measurement equipment 617 can calculate an actual resistance across via chain 602.

As described in connection with FIGS. 5A and 5B, an estimated or expected resistance for a via chain can be calculated. The measured resistance value from measurement equipment 618 may be compared to the estimated resistance value. Deviations in the measured resistance value, such as significant increases in resistance, compared to the estimated value indicate the possibility that a crack or other damage are present in laminated substrate 601.

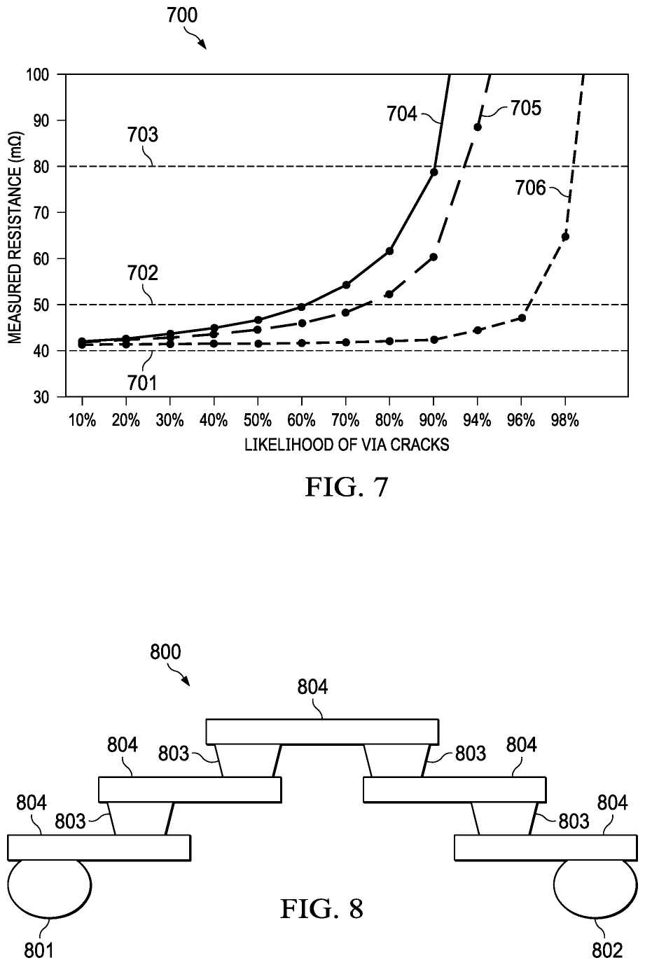

FIG. 7 is a graph 700 illustrating the likelihood that cracked microvias are present in a laminate substrate (x-axis) versus measured resistance (y-axis) for an example via chain design. In the example, the via chain design has an estimated resistance of 40 mΩ, which is indicated by line 701. Deviations in the resistance measurement of 25% (i.e., 50 mΩ) and 100% (i.e., 80 mΩ) are indicated by lines 702 and 703, respectively. Resistance measurements across laminate substrates having this via chain design are expected to be 40 mΩ or within an acceptable tolerance. Plot 704 represents resistance measurements expected when all of the vias in the via chain design have a crack. Plot 705 represents resistance measurements expected when half of the vias in the via chain design have a crack. Plot 706 represents resistance measurements expected when one via in the via chain design has a crack.

Graph 700 may represent resistance measurements for via chain 602 in one example. If the via chain resistance is measured at 50 mΩ, such as by measurement equipment 617 in FIG. 6, then the resistance is 25% higher than expected. This indicates a probability of 96% that a single via is cracked, 75% that half of the vias are cracked, or 60% that all of the vias are cracked. If the via chain resistance is measured at 80 mΩ, then the resistance is 100% higher (2 times higher) than expected. This indicates a probability of 98% that a single via is cracked, 92% that half of the vias are cracked, or 88% that all of the vias are cracked. Cracking in via chain 602 suggests that internal wiring structure 615 will have similar cracks, which will cause proportionate degradation in the operation of semiconductor package 600.

Although FIG. 6 illustrates four-wire testing of semiconductor package 600, two-wire testing may also be performed, such as if only two solder balls 607a,b were available.

FIG. 6 illustrates testing of an assembled semiconductor package 600. In other examples, laminate substrate 601 may be tested without IC die 608 attached. Laminate substrate 601 may be tested at various points in the product life cycle, such as at a substrate vendor, at an Outsourced Semiconductor Assembly and Test (OSAT) service, at semiconductor device assembly, at a component manufacturer, or at an end-user.

Via chain 602 is shown as a linear configuration of core vias and microvias relative to substrate 601 for simplification of the description of FIG. 6. In other examples, the via chain may have a linear, diagonal, curved, serpentine, circular, spiral, or any other pattern of vias to ensure sufficient coverage of the substrate for testing. In further examples, microvias may be stacked, offset, or a combination of stacked and offset. The via chain may have varying lengths of conductive plating separating offset microvias. The microvias may go through some or all of the build-up layers. The microvias may be evenly distributed across all build-up layers or may be concentrated in select build-up layers.

FIG. 8 illustrates an example microvia configuration adapted for creating a long via chain. Via chain 800 extends between solder balls 801 and 802. Microvias are arranged in an offset configuration. Conductive plating 804 may have varying lengths to allow for the creation of a long via chain 800 by increasing the lateral offset of microvias 803.

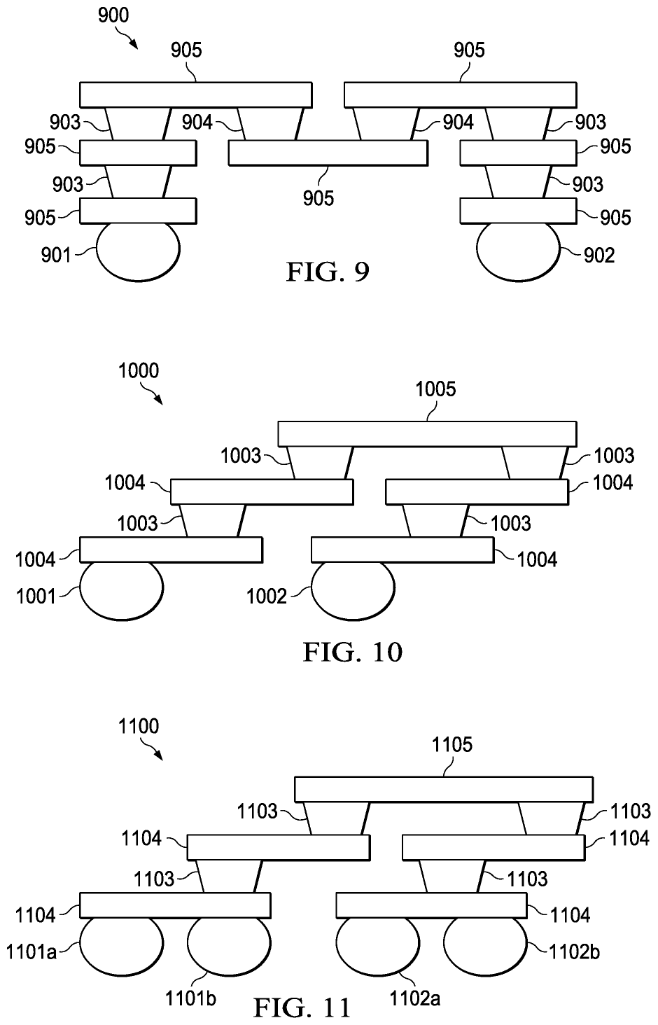

FIG. 9 illustrates an example microvia configuration having a hybrid combination of stacked and offset microvias. Via chain 900 extends between solder balls 901 and 902. Select microvias 903 are arranged in a stack configuration. Other microvias 904 are arranged in an offset confirmation relative to each other and to the stacked microvias 903. Conductive plating 905 may have varying lengths to allow varying lateral offsets of the microvias 903, 904.

FIG. 10 illustrates a loop-back microvia configuration. Via chain 1000 extends between a single pair of solder balls 1001 and 1002. Microvias 1003 and conductive plating layers 1004 are arranged in an offset configuration. The microvias 1003 are offset away from solder ball 1001 in a first direction until the via chain 1000 reaches a top conductive layer 1005. After reaching conductive layer 1005, the microvias 1003 are arranged in an offset configuration toward solder ball 1001 in a second direction opposite the first direction. This allows the endpoint solder balls 1001 and 1002 to be in close proximity. In some examples, having the endpoint solder balls close together may simplify a testing process.

FIG. 11 illustrates a loop-back microvia configuration that is similar to FIG. 10 with additional solder balls. Via chain 1100 extends between a first pair of solder balls 1101a,b and a second pair of solder balls 1102a,b. Microvias 1103 and conductive plating layers 1104 are arranged in an offset configuration. The microvias 1103 are offset away from solder ball 1101 in a first direction until the via chain 1100 reaches a top conductive layer 1105. After reaching conductive layer 1105, the microvias 1103 are arranged in an offset configuration toward solder ball 1101 in a second direction opposite the first direction. In addition to having additional solder balls at each of the via chain, the endpoint solder balls are all in close proximity.

The via chain configurations illustrated in FIGS. 2, 3, 4, 6, and 8-11 are example arrangements only and are not intended to be limiting of via chain designs. Various one of the example designs herein may be combined to form via chains having any configuration required to test a laminate substrate.

The via chains illustrated herein provide built-in monitoring for each individual substrate unit, which allows for 100% testing of laminate substrates to assist in achieving a 0 DPPM target for some applications. The via chains can be tested at all stages of manufacture, which increases the opportunity to detect substrate quality issues at early stage of the supply chain. The proposed serial via chain can be designed for all types of laminated substrate devices, including singulation-based FCBGA, strip-based Flip Chip-Chip Scale Package (FCCSP), and Embedded Trace Substrate (ETS).

Solder balls in a BGA may be selected in high stresses regions for monitoring which allows for a redundant or dummy electrical netlist.

The use of an embedded via chain allows for replacement of substrate-level four-wire testing on all key signal netlists thereby providing a cost reduction to manufacturers. The embedded via chain allows for validation of substrate quality corner conditions.

Measurements of via chain data across multiple units and sheets allow for the collection of substrate quality and reliability data through mass productions. A manufacturer may implement different stacked and/or staggered via designs into a serial via chain coupon within one device. This data may be used to guide updates to substrate design rules, for example.

An example semiconductor package comprises an integrated circuit die having a first surface with a first array of electrode pads and a laminate substrate having an upper surface with a second array of electrode pads, wherein electrode pads of the first array are connected to corresponding electrode pads of the second array using a solder bump. The integrated circuit die may be mounted on the laminated substrate in a “flip chip” configuration. The laminate substrate has a lower surface with a third array of electrode pads. The electrodes in the third array are coupled to corresponding electrodes of the second array by a laminate wiring structure within the laminate substrate. The semiconductor package includes individual solder balls that are attached to selected electrodes of the third array. The solder balls are adapted to electrically connect the selected electrodes of the third array to contacts on a printed circuit board. A first electrode on the lower surface is coupled to a second electrode on the lower surface by a chain of vias through the laminate substrate. The chain of vias may include core vias in a laminate core layer and microvias in one or more dielectric or build-up layers. The microvias may be created by laser drilling in the dielectric or build-up layers. The dielectric or build-up layers may comprise layers both above and below the laminate core layer. A top solder resist layer is attached above a top dielectric layer, and a bottom solder resist layer is attached below a bottom dielectric layer. The chain of vias includes microvias in a plurality of coreless dielectric layers. In various examples, a majority of microvias in the chain of vias may be arranged in a stacked format, in an offset format, or both groups of stacked microvias and groups of offset microvias.

The chain of vias is not connected to the integrated circuit die; however, the core vias and microvias in the chain of vias are formed in laminate substrate layers used by the laminate wiring structure used to communicate with the integrated circuit die. The first electrode and the second electrode on the lower surface are not electrically connected to the integrated circuit die. The chain of vias and the laminate wiring structure are constructed by a same process to create the laminate substrate.

Solder balls are attached to selected electrodes of the third array, which are used to communicating with the integrated circuit die. Each selected electrode may have two solder balls attached. A first pair of solder balls may be attached to the first electrode, and a second pair of solder balls may be attached to the second electrode. The first and second pair of solder balls may be configured to support four-wire Kelvin resistance measurement testing of the chain of vias or other testing, such as two-wire testing. The number of microvias in the chain of vias may be selected to create a target resistance value across the chain of vias.

An underfill resin is disposed between the first surface of the IC die and the upper surface of the laminate substrate. A lid may be attached to the package to cover the integrated circuit die and the upper surface of the laminate substrate.

There are tens of steps in a substrate manufacturing process. There are many factors to manage in the process, such as temperature, dwell time, chemical quality, and machine operation. The complicated manufacturing process makes it difficult to find root cause when a low DPPM issue arises. Testing of individual units ensures that failed units are identified as early as possible.

An example method of testing substrate integrity comprises providing a semiconductor package including an integrated circuit die coupled to a laminate substrate, wherein the laminate substrate has a surface with a plurality of contacts, and wherein a first contact on the surface is coupled to a second contact on the surface by a chain of vias through the laminate substrate; connecting voltage probes to the first contact and the second contact; connecting current probes to the first contact and the second contact; determining a resistance value across the chain of vias based upon voltage and current measurements generated using the voltage and current probes; and evaluating whether the resistance value indicates cracking in the chain of vias. Cracking in the chain of vias is indicated when the resistance value exceeds a target value by a threshold amount.

Each of the first contact and the second contact may include a first solder ball and a second solder ball. The voltage probes may be connected to the respective first solder balls, and the current probes connected to the respective second solder balls. The first solder balls and the second solder balls on each of the first and second contacts may be dummy balls that do not connect to the integrated circuit die.

While various examples of the present disclosure have been described above, it should be understood that they have been presented by way of example only and not limitation. Numerous changes to the disclosed examples can be made in accordance with the disclosure herein without departing from the spirit or scope of the disclosure. Modifications are possible in the described embodiments, and other embodiments are possible, within the scope of the claims. Thus, the breadth and scope of the present invention should not be limited by any of the examples described above. Rather, the scope of the disclosure should be defined in accordance with the following claims and their equivalents.

What is claimed is:

1. A semiconductor package, comprising:
an integrated circuit (IC) die having a first surface with a first array of electrode pads;
a laminate substrate having an upper surface with a second array of electrode pads, wherein electrode pads of the first array are connected to corresponding electrode pads of the second array using a solder bump;
the laminate substrate having a lower surface with a third array of electrode pads, wherein electrodes of the third array are coupled to corresponding electrodes of the second array by a laminate wiring structure within the laminate substrate; and
a first electrode on the lower surface coupled to a second electrode on the lower surface by a chain of vias through the laminate substrate.

2. The semiconductor package of claim 1, wherein the chain of vias includes core vias in a laminate core layer and microvias in one or more dielectric layers.

3. The semiconductor package of claim 2, wherein the one or more dielectric layers comprise dielectric layers both above and below the laminate core layer.

4. The semiconductor package of claim 3, further comprising a top solder resist layer above a top dielectric layer and a bottom solder resist layer below a bottom dielectric layer.

5. The semiconductor package of claim 1, wherein the chain of vias includes microvias in a plurality of coreless dielectric layers.

6. The semiconductor package of claim 1, wherein the chain of vias is not connected to the IC die.

7. The semiconductor package of claim 1, wherein a majority of microvias in the chain of vias are arranged in a stacked format.

8. The semiconductor package of claim 1, wherein a majority of microvias in the chain of vias are arranged in an offset format.

9. The semiconductor package of claim 1, wherein the chain of vias includes both groups of stacked microvias and groups of offset microvias.

10. The semiconductor package of claim 1, further comprising:
individual solder balls attached to selected electrodes of the third array, wherein the solder balls are adapted to electrically connect the selected electrodes of the third array to contacts on a printed circuit board.

11. The semiconductor package of claim 1, further comprising:
solder balls attached to selected electrodes of the third array, wherein each selected electrode has two solder balls attached.

12. The semiconductor package of claim 1, wherein a first pair of solder balls are attached to the first electrode and a second pair of solder balls are attached to the second electrode, and wherein the first and second pair of solder balls are configured to support four-wire Kelvin resistance measurement testing of the chain of vias.

13. The semiconductor package of claim 1, wherein a number of microvias in the chain of vias is selected to create a target resistance value across the chain of vias.

14. The semiconductor package of claim 1, wherein the chain of vias and the laminate wiring structure are constructed by a same process to create the laminate substrate.

15. The semiconductor package of claim 1, further comprising:
an underfill resin disposed between the first surface of the IC die and the upper surface of the laminate substrate; and
a lid covering the IC die and the upper surface of the laminate substrate.

16. A method of testing substrate integrity, comprising:
providing a semiconductor package including an integrated circuit (IC) die coupled to a laminate substrate, wherein the laminate substrate has a surface with a plurality of contacts, and wherein a first contact on the surface is coupled to a second contact on the surface by a chain of vias through the laminate substrate;
connecting voltage probes to the first contact and the second contact;
connecting current probes to the first contact and the second contact;
determining a resistance value across the chain of vias based upon voltage and current measurements generated using the voltage and current probes; and
evaluating whether the resistance value indicates cracking in the chain of vias.

17. The method of claim 16, wherein cracking in the chain of vias is indicated when the resistance value exceeds a target value by a threshold amount.

18. The method of claim 16, wherein each of the first contact and the second contact include a first solder ball and a second solder ball, and wherein the voltage probes are connected to the respective first solder balls and the current probes are connected to the respective second solder balls.

19. The method of claim 18, wherein the first solder balls and the second solder balls on each of the first and second contacts are dummy balls that do not connect to the IC die.
